(19) United States
(12) Patent Application Publication
(10) Pub. No.: US 2026/0354176 A1
(43) Pub. Date: Nov. 5, 2026

(54) MONOLOTHIC MICROWAVE INTEGRATED CIRCUIT WITH NON-METALLIC HEAT SPREADER AND REDISTRIBUTION LAYER

(71) Applicant: Qorvo US, Inc., Greensboro, NC (US)

(72) Inventors: Kevin Anderson, Plano, TX (US); Tarak Railkar; Jeffrey Miller, Allen, TX (US); Andrew Ketterson, Dallas, TX (US)

(21) Appl. No.: 19/558,779

(22) Filed: Mar. 6, 2026

Related U.S. Application Data
(60) Provisional application No. 63/799,099, filed on May 2, 2025.

(51) Int. Cl. H10W 40/20; H10W 70/65

(52) U.S. Cl. CPC H10W 40/233; H10W 70/65

(57) ABSTRACT

A monolithic microwave integrated circuit (MMIC) device includes: a MMIC die having a top surface and an active circuit layer; a non-metallic heat spreader coupled to the top surface of the MMIC die by a micro bond line attachment; and a redistribution layer coupled to the active circuit layer of the MMIC die.

### CROSS REFERENCE TO RELATED APPLICATIONS

This application claims the priority benefit under 35 U.S.C. §119(e) of U.S. Provisional Patent Application No. 63/799,099 filed 02 May 2025, which is hereby incorporated by reference in its entirety as though fully set forth herein.

### TECHNICAL FIELD

The subject matter described herein relates to devices, systems, and methods for providing heat dissipation, mechanical support, and electrician fanout capability to a monolithic microwave integrated circuit (MMIC). This MMIC with non-metallic heat spreader and redistribution layer has particular but not exclusive utility for high-power radio frequency (RF) applications and phased-array antennas.

### BACKGROUND

A monolithic microwave integrated circuit (MMIC) chip may be referred to as a die, and may for example be fabricated with copper or gold traces on a silicon (Si), gallium arsenide (GaAs) or gallium nitride (GaN) wafer. In some cases, a MMIC die may be packaged in a durable housing or chip-scale package. However, in other cases, it may be desirable to supply a MMIC to an RF equipment manufacturer as a bare die. With a significant increase in the power handling levels of MMICs over the past several decades (e.g., multiple watts vs. less than 1 watt), it is sometimes desirable to mount the MMIC to a metallic heat spreader, e.g., a mechanical support component that is thermally conducting, such that heat generated by the MMIC may be transmitted to all parts of the heat spreader and either dissipated into the environment or transferred to a heat sink or cooling system. Such a heat spreader may in some cases be referred to as a “tab”, and a bare MMIC die mounted to the heat spreader may be referred to as a “tabbed” MMIC.

The information included in this Background section of the specification, including any references cited herein and any description or discussion thereof, is included for technical reference purposes only and is not to be regarded as subject matter by which the scope of the disclosure is to be bound.

### SUMMARY

Disclosed is a monolithic microwave integrated circuit (MMIC) with non-metallic heat spreader and redistribution layer (RDL), which provides mechanical support to a MMIC die, while dissipating heat generated by the MMIC die during operation. The MMIC with non-metallic heat spreader and RDL disclosed herein has particular, but not exclusive, utility for high-power radio frequency systems and phased-array antennas.

One general aspect includes a monolithic microwave integrated circuit (MMIC) device. The monolithic microwave integrated circuit includes a MMIC die, which may include a top surface and an active circuit layer. The circuit also includes a non-metallic heat spreader coupled to the top surface of the MMIC die by a micro bond line attachment. The circuit also includes a redistribution layer coupled to the active circuit layer of the MMIC die.

Implementations may include one or more of the following features. In some embodiments, the MMIC die may include silicon, gallium arsenide, or gallium nitride, or the non-metallic heat spreader may include silicon carbide, aluminum nitride, or diamond, or the micro bond line attachment may include a sintered metal. In some embodiments, the non-metallic heat spreader has a thermal conductivity of at least 100 w/mk. In some embodiments, the MMIC device may include a package material at least partially covering the non-metallic heat spreader and MMIC die. In some embodiments, the MMIC device may include a thermally conductive interfacial material on a top surface of the non-metallic heat spreader. In some embodiments, the MMIC device may include a dielectric MMIC coat disposed between the active circuit layer and the redistribution layer. In some embodiments, the MMIC device may include a land grid array or ball grid array disposed on a bottom surface of the redistribution layer.

One general aspect includes a method for packaging a monolithic microwave integrated circuit (MMIC). The method includes providing a MMIC die that may include a top surface and an active circuit layer. The method also includes coupling a non-metallic heat spreader to the top surface of the MMIC die by a micro bond line attachment; and coupling a redistribution layer to the active circuit layer of the MMIC die.

Implementations may include one or more of the following features. In some embodiments, the MMIC die may include silicon, gallium arsenide, or gallium nitride, or the non-metallic heat spreader may include silicon carbide, aluminum nitride, or diamond, or the micro bond line attachment may include a sintered metal. In some embodiments, the non-metallic heat spreader has a thermal conductivity of at least 100 w/mk. In some embodiments, the method may include covering at least a portion of the non-metallic heat spreader and MMIC die with a packaging material. In some embodiments, the method may include a coating a thermally conductive interfacial material on a top surface of the non-metallic heat spreader. In some embodiments, the method may include a coating a dielectric MMIC material between the active circuit layer and the redistribution layer. In some embodiments, the method may include coupling a land grid array or ball grid array to a bottom surface of the redistribution layer.

One general aspect includes a wireless device. The wireless device includes a monolithic microwave integrated circuit (MMIC) device, which may include: a MMIC die with a top surface and an active circuit layer, a non-metallic heat spreader coupled to the top surface of the MMIC die by a micro bond line attachment, a redistribution layer coupled to the active circuit layer of the MMIC die, and a land grid array or ball grid array disposed on a bottom surface of the redistribution layer.

Implementations may include one or more of the following features. In some embodiments, the MMIC die may include silicon, gallium arsenide, or gallium nitride, or the non-metallic heat spreader may include silicon carbide, aluminum nitride, or diamond, or the micro bond line attachment may include a sintered metal. In some embodiments, the non-metallic heat spreader has a thermal conductivity of at least 100 w/mk. In some embodiments, the wireless device may include a package material at least partially covering the non-metallic heat spreader and MMIC die. In some embodiments, the wireless device may include a thermally conductive interfacial material on a top surface of the non-metallic heat spreader. In some embodiments, the wireless device may include a dielectric MMIC coat disposed between the active circuit layer and the redistribution layer.

This Summary is provided to introduce a selection of concepts in a simplified form that are further described below in the Detailed Description. This Summary is not intended to identify key features or essential features of the claimed subject matter, nor is it intended to limit the scope of the claimed subject matter. A more extensive presentation of features, details, utilities, and advantages of the MMIC with non-metallic heat spreader and RDL, as defined in the claims, is provided in the following written description of various embodiments of the disclosure and illustrated in the accompanying drawings.

### BRIEF DESCRIPTION OF THE DRAWINGS

Illustrative embodiments of the present disclosure will be described with reference to the accompanying drawings, of which:

FIG. 1 is a bottom perspective view of an example MMIC with non-metallic heat spreader and RDL, in accordance with at least one embodiment of the present disclosure.

FIG. 2 is a bottom perspective view of an example MMIC with non-metallic heat spreader and RDL, in accordance with at least one embodiment of the present disclosure.

FIG. 3 is a perspective view of a wafer level process for fabricating the MMIC with non-metallic heat spreader and RDL, in accordance with at least one embodiment of the present disclosure.

FIG. 4 is a side cross-sectional view of an example MMIC with non-metallic heat spreader and RDL, in accordance with at least one embodiment of the present disclosure.

FIG. 5 is a side cross-sectional view of an example MMIC with non-metallic heat spreader and RDL, in accordance with at least one embodiment of the present disclosure.

FIG. 6 is a side cross-sectional view of an example MMIC with non-metallic heat spreader and RDL, in accordance with at least one embodiment of the present disclosure.

FIG. 7 is a side cross-sectional view of an example MMIC with non-metallic heat spreader and RDL, in accordance with at least one embodiment of the present disclosure.

FIG. 8 is a side cross-sectional view of an example MMIC 800 with non-metallic heat spreader 102 and RDL 142, in accordance with at least one embodiment of the present disclosure.

FIG. 9 is a side cross-sectional view of an example MMIC with non-metallic heat spreader and RDL, in accordance with at least one embodiment of the present disclosure.

FIG. 10 is a side cross-sectional view of an example MMIC with non-metallic heat spreader and RDL, in accordance with at least one embodiment of the present disclosure.

FIG. 11 is a side cross-sectional view of an example MMIC with non-metallic heat spreader and RDL, in accordance with at least one embodiment of the present disclosure.

FIG. 12 is a schematic, diagrammatic view of an electronic device or a wireless device comprising a MMIC, in accordance with at least one embodiment of the present disclosure.

FIG. 13 is a schematic, diagrammatic representation, in flow diagram form, of an example MMIC fabrication method, in accordance with at least one embodiment of the present disclosure.

### DETAILED DESCRIPTION

In accordance with at least one embodiment of the present disclosure, a MMIC with non-metallic heat spreader and RDL is disclosed which provides robust mechanical support for the MMIC die, as with a metallic heat spreader, but also provides a heat spreader whose coefficient of thermal expansion is a better match for that of the MMIC die as compared with a metallic heat spreader.

In addition to an integrated thermal management solution, current and forward-looking applications are pointing to a need for integrating an interconnect solution for MMIC dies. It is an object of the present disclosure to provide a fine-pitch, interconnect enabled and tabbed MMIC that RF equipment manufacturers can integrate into their products. Thus, in some cases, a MMIC die may be mounted to a redistribution layer (RDL) that allows contacts on the bottom surface of the MMIC to be connected to a printed circuit board without the need for the board to be wired for that specific MMIC, and may for example allow the MMIC to have the same pinout as a different chip, or may allow a wire-bond chip to be repurposed as a flip-chip. Such RDLs may for example be made of dielectric material with gold or copper traces, and may have a limited ability to absorb or dissipate heat, particularly at the high heat fluxes generated by a MMIC.

The present disclosure provides a heat spreader in contact with the MMIC die. Silicon is also a moderately robust candidate material, but its thermal conductivity can be a limiting factor for some high-power applications. Other example materials include but are not limited to silicon carbide (SiC), aluminum nitride, or diamond, all of which are mechanically much tougher than silicon. For example, the fracture toughness of SiC is 2.5-6.8 MPa m^{0.5}, the fracture toughness of aluminum nitride is 4.0-4.6 MPa m^{0.5}, and the fracture toughness of diamond is around 2.0 MPa m^{0.5}, whereas the fracture toughness of silicon (Si) is 0.7-1.3 MPa m^{0.5}. SiC also provides high thermal conductivity (e.g., 490 W/mK for SiC, vs. 140 W/mK for silicon – a 3.5x improvement) and high mechanical toughness (e.g., SiC offers 1.9-9.7 times as much fracture toughness as silicon). Additionally, the substrate heat spreader’s crystalline structure may be configured in a manner that provides enhanced thermal conductivity. For example, dopants or impurities might be present in the heat spreader that alter or improve the thermally conductive properties of SiC alone. The concentration of the impurities would be present according to the desired properties.

A typical heat spreader using current technology may be made of copper, and may have a coefficient of thermal expansion of 17-19 x 10⁻⁶/° C., which is approximately three times the 5.6 x 10⁻⁶/° C. of GaN or the 5.4 x 10⁻⁶/° C. of GaAs – a significant mismatch. Similarly, a metallic heat spreader made of copper-molybdenum (CuMo) may have a coefficient of thermal expansion (CTE) of 9-12 x 10⁻⁶/° C. CuMo is an alloy, so its properties depend on the exact composition. A CTE of 9-12 parts per million is appropriate for most CuMo alloys used for thermal management. By contrast, SiC has a coefficient of thermal expansion of approximately 4.0 x 10⁻⁶/° C., which is a much better match for the MMIC die materials, and thus decreases mechanical stress and the concomitant risk of delamination between the MMIC die and the heat spreader. A heat spreader made from SiC thus offers capabilities not demonstrated by, nor contemplated for, traditional heat spreaders made from metallic materials.

In some embodiments, the MMIC with non-metallic heat spreader and RDL may also be coated on the top and sides with a conformal layer, multiple conformal layers, or a molding compound such as epoxy molding compound or EMC.

Thus, the MMIC with non-metallic heat spreader and RDL offers clear advantages over existing MMICs with metallic heat spreaders. For purposes of this document, “thermally conductive” shall mean a material or component with a thermal conductivity of at least 100 W/mK (e.g., between 100 and infinity W/mK).

The non-metallic heat spreader provides mechanical support to MMICs, as they get thinner from the current 100 um down to 50 um, 25 um and beyond. Mechanical handling is an important aspect of reducing yield loss, and as the thickness of MMICs continues to reduce, the non-metallic heat spreader provides mechanical robustness and additional benefits as are outlined herein.

The MMIC with non-metallic heat spreader and RDL leverages wafer-fab like capabilities, and also enables superior, integrated thermal management solutions for bare MMIC die sales. When the MMIC with non-metallic heat spreader and RDL is properly designed and fabricated, its thermal performance can be significantly superior to that of the bare-die itself. The methodology described herein also enhances mechanical reliability performance through three-dimensional heterogeneous integration (3DHI). Use of advanced fab-like processes and technologies can make the MMIC with non-metallic heat spreader and RDL mechanically superior to and more robust than, MMIC dies with metallic heat spreaders, thus increasing reliability.

The MMIC die is attached to the heat spreader by a micro-bond line attachment (MBLA) material. The MBLA may comprise of a sintered metal material such as Ag, Au, Cu, and other materials forming an intimate bond between an interface of the MMIC and the heat spreader, or may be a solder material such as alloys of Sn, Au, In, Ag, Bi, and other materials.

Embodiments of the present disclosure contemplate configurations of GaN MMIC product(s) with greater integration and thermal management, translating into more applications where the MMIC can be introduced. The tabbed MMIC scaled interconnect package provides chip scaled fan-out or fan-in routing where required, thus supporting tighter interconnect pitch and smaller MMICs, without adversely impacting next level assembly (NLA) considerations. The tabbed MMIC scaled interconnect package enables superior, integrated thermal management solution for Qorvo's bare MMIC die by coupling a thermally conductive material (e.g., SiC, Si, etc.) tab with a micro-bond-line attachment material. Use of non-metallic thermal spreaders assists with managing the coefficient of thermal expansion based stress at the spreader-to-MMIC interface. Further, useof advanced fab-like processes and/or RDL like technologies (employing polyimide, polybenzoazoles (PBO), and Ajinomoto buildup film (ABF), for example) can make tabbed MMIC scaled package offerings that are mechanically superior and robust, thus increasing the reliability of the MMIC in field applications.

These descriptions are provided for exemplary purposes only, and should not be considered to limit the scope of the MMIC with non-metallic heat spreader and RDL. Certain features may be added, removed, or modified without departing from the spirit of the claimed subject matter.

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

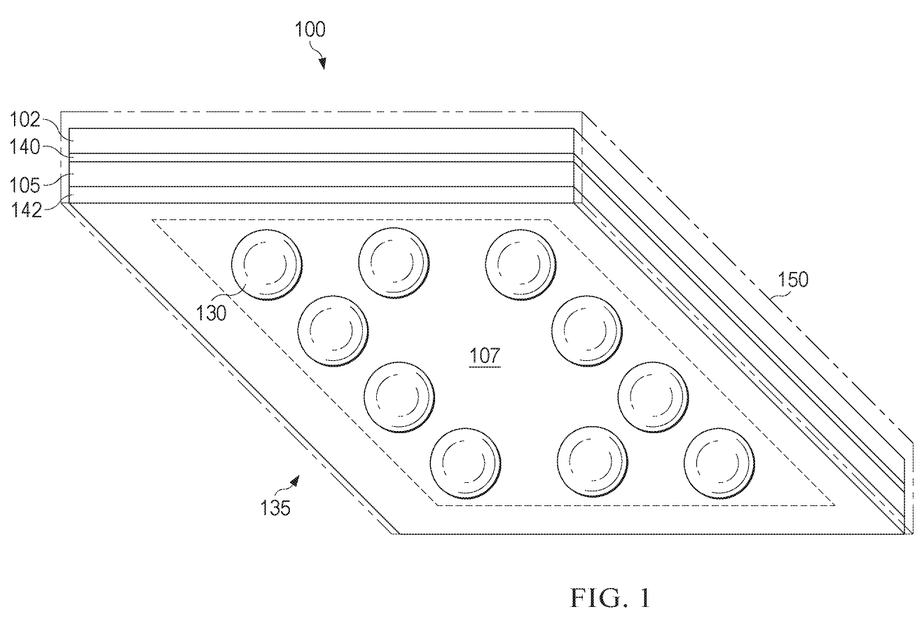

FIG. 1 is a bottom perspective view of an example MMIC 100 with non-metallic heat spreader 102 and RDL 142, in accordance with at least one embodiment of the present disclosure. The MMIC 100 includes a MMIC die 105 (e.g., GaN, GaAs) and a heat spreader (e.g., SiC). The top or back side of the MMIC die 105 is attached to the bottom or front side of the heat spreader 102 by a micro-bond line attachment (MBLA) 140. The MBLA 140 may include a sintered metal material such as Ag, Au, Cu, and other materials forming an intimate bond between an interface of the MMIC die 105 and the heat spreader 102, or may be a solder material such as alloys of Sn, Au, In, Ag, Bi, and other materials.

The MMIC die 105 includes an active circuit plane 107, which is in mechanical, thermal, and electrical contact with a redistribution layer (RDL) 142. The RDL 142 may include a plurality of metal and dielectric layer(s) formed by metal (e.g., Cu, Au, etc.) and polymeric films such as polyimide (PI), polybenzoxazole (PB), benzocyclobutene (BCB), Ajinomoto buildup film (ABF) or others. The RDL may include metal traces and/or conductive vias that may for example be defined using a semi-additive process (SAP) using photoresist and metal electroplating or, less commonly, through a subtractive process where the metal traces are etched using a photoresist-defined mask. In some embodiments, the metal traces may be formed using damascene process using polymeric dielectrics or more commonly inorganic dielectric layers (e.g., tetraethyl orthosilicate (TEOS)). To connect the RDL to the next higher level of the assembly, a solder or other alloy conductive materials is deposited over the RDL pads (not shown) a ball grid array (BGA) 135 comprising solder balls 130. The RDL functions to connect pads on the active circuit plane 107 to the ball grid array 135.

The MMIC 100 may also be coated with a package material 150, which may for example be an epoxy mold compound (EMC), or other mold compound (MC), or one or more layers of a conformal coating. The package material 150 may for example protect the edges of the MMIC die 105, active circuit plane 107, and RDL 142 from damage, electrical shorts, or other unwanted contact. Because the thickness of the package material 150 is on the order of about 50 um to about 300 um, it does not significantly affect the dimensions of the total package. In some cases, the package material 150 may be or include an electromagnetic shield.

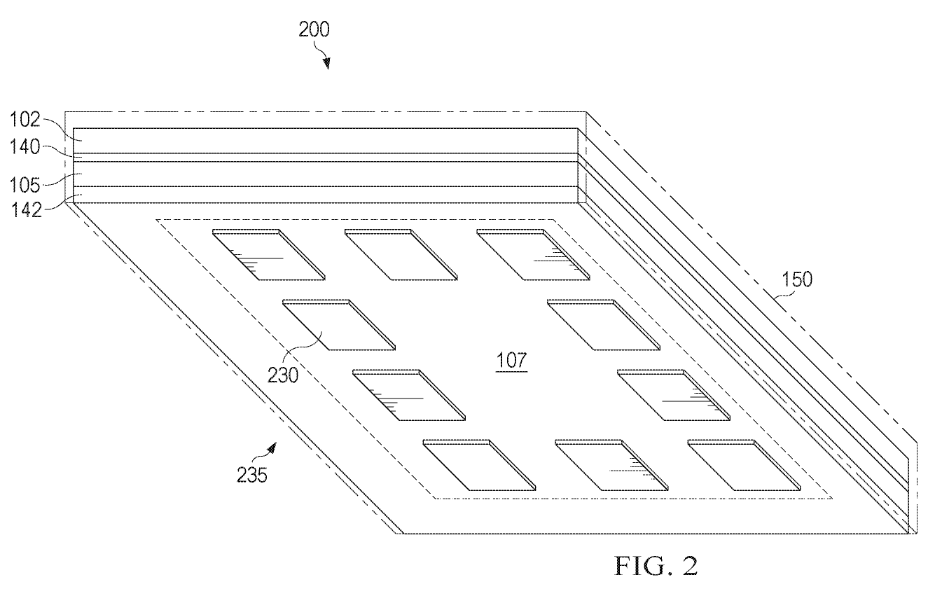

FIG. 2 is a bottom perspective view of an example MMIC 200 with non-metallic heat spreader 102 and RDL 142, in accordance with at least one embodiment of the present disclosure. Visible are the MMIC die 105, active circuit plane 107, MBLA 140, heat spreader 102, RDL 142, and package material 150. The MMIC 200 is similar to the MMIC 100 of FIG. 1, except that the ball grid array BGA) 135 has been replaced with a land grid array (LGA) 235 comprising lands or pads 230.

The contact pads (not shown) on the active circuit layer 107 provide mechanical, electrical and/or thermal paths through the RDL. The MMIC die 105 is attached to the heat spreader 102 by the MBLA 140. As described above, the heat spreader 102 may be made of SiC or other suitable materials, and may have a thickness up to about 725 um, and may be optionally configured to thicknesses down to about 25 um in some embodiments.

Surrounding the heat spreader 102, MMIC die 105, and the RDL 142 may be an optional package material 150. The package material 150 may include one or more layers of conductive and/or insulating materials. The package material 150 in an embodiment may include a conformally spray-coated dielectric and/or conductive sintered material to provide overall mechanical stability and provide electrical isolation from RF signals outside of the MMIC 200. In an embodiment, the package material 150 may include a polymer coating such as a mold compound. In some embodiments the package material 150 may substantially extend over the sides of the heat spreader 102, MMIC die 105, active circuit plane 107, and RDL 142, and in other embodiments, the package material may extend over the sides of only the heat spreader 102, MMIC die, and active circuit plane 107.

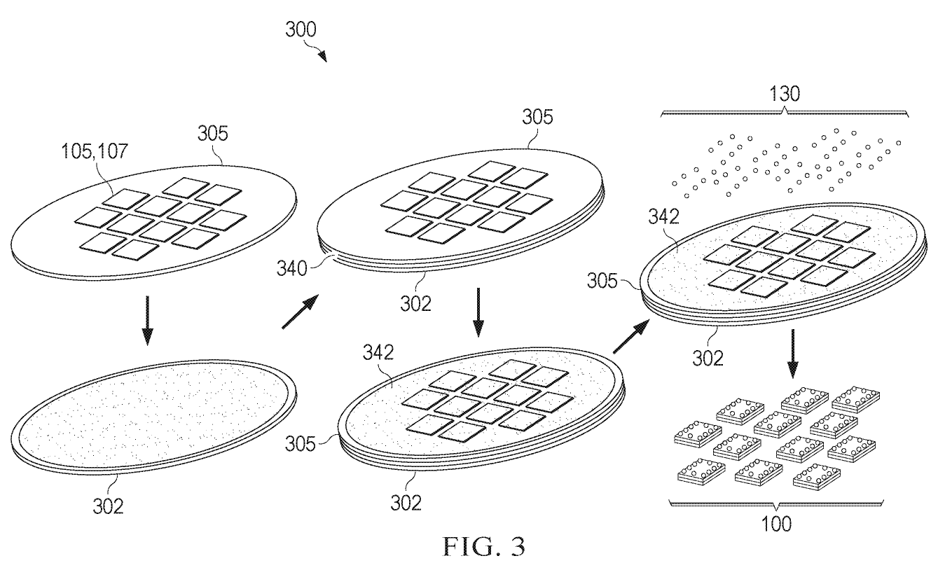

FIG. 3 is a perspective view of a wafer level process for fabricating the MMIC with non-metallic heat spreader and RDL, in accordance with at least one embodiment of the present disclosure. In a first exemplary fabrication step, a III-V wafer 305 (e.g., a GaN wafer) having a plurality of MMIC dies 105, each with a circuit plane 107, is bonded to a SiC wafer 302. In an example, the III-V wafer 305 is bonded to the SiC wafer 302 via the MBLA 340 formed on the mating surfaces of the wafers 305, 302. The MBLA 340 may include a film-based sintered metal such as Au, Ag, or Cu that is cured to form a conductive layer of about 5 um or about less than 1 um thickness. In a second exemplary fabrication step, once the MBLA 340 is cured for the bonded wafers, an RDL 342 is formed over the top surface of the III-V wafer 305, and built-up according to the desired number of dielectric and metal layer(s).

In a third exemplary fabrication step, solder balls 130 are bonded to the RDL 342 to form ball grid arrays. In a fourth fabrication step, the individual MMICs 100 are diced or otherwise singulated from the wafer stack.

It is understood that the MMIC with non-metallic heat spreader and RDL may be configured to support not only one MMIC, but multiple MMICs. The MMIC with non-metallic heat spreader and RDL may also be fabricated as individual piece parts wherein an individual heat spreader is attached to the MMIC die and later re-constituted onto a carrier to form the RDL. These MMICs can all be fabricated from one semiconductor node or multiple nodes, and support integration of MMICs fabricated from different semiconductor materials, such as Si, GaAs, GaN, etc.

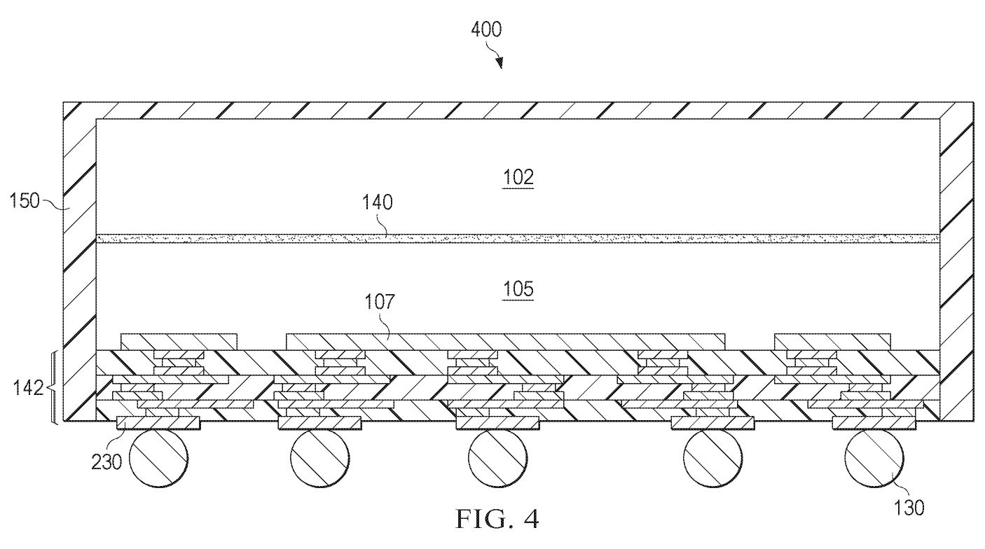

FIG. 4 is a side cross-sectional view of an example MMIC 400 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, package material 150, LGA lands 230, and BGA solder balls 130. In the example shown in FIG. 4, the package material 150 covers the top of the heat spreader 102, as well as the sides of the heat spreader 102, MMIC die 105, and RDL 142.

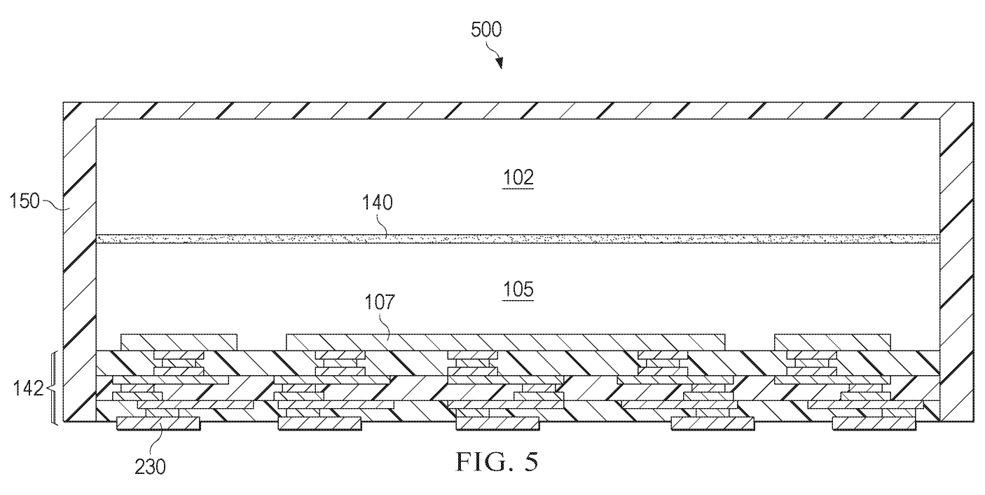

FIG. 5 is a side cross-sectional view of an example MMIC 500 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, package material 150, and LGA lands 230. In the example shown in FIG. 5, the package material 150 covers the top of the heat spreader 102, as well as the sides of the heat spreader 102, MMIC die 105, and RDL 142.

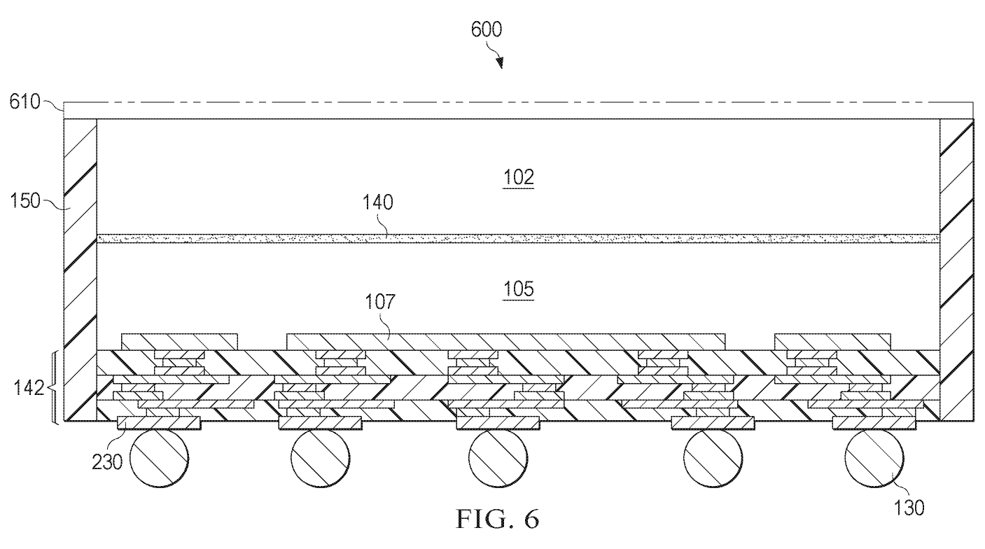

FIG. 6 is a side cross-sectional view of an example MMIC 600 with non-metallic heat 102 spreader and RDL 142, in accordance with at least one embodiment of the present disclosure. Visible are the heat spreader 102, MMIC die 105, micro bond line attachment (MBLA 140), active circuit layer 107, RDL 142, package material 150, LGA lands 230, and BGA solder balls 130. In the example shown in FIG. 6, the package material 150 has been ground off of, or otherwise removed from, the top of the heat spreader 102, but still covers the sides of the heat spreader 102, MMIC die 105, and RDL 142. Disposed upon the exposed surface of the heat spreader 102 may be an optional thermally conductive interfacial material (TIM) 610 that may for example interface with a heat sink (not shown). Example TIMs include but are not limited to epoxies, sinterable or hybrid epoxies, or solder materials.

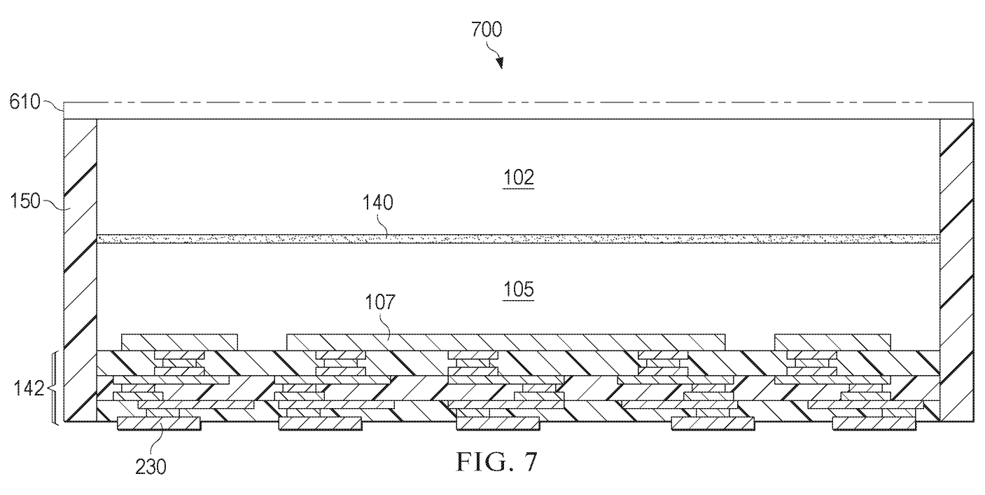

FIG. 7 is a side cross-sectional view of an example MMIC 700 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, package material 150, and LGA lands 230. In the example shown in FIG. 7, the package material 150 has been ground off of, or otherwise removed from, the top of the heat spreader 102, but still covers the sides of the heat spreader 102, MMIC die 105, and RDL 142. Disposed upon the exposed surface of the heat spreader 102 may be an optional thermally conductive interfacial material (TIM) 610 that may for example interface with a heat sink (not shown).

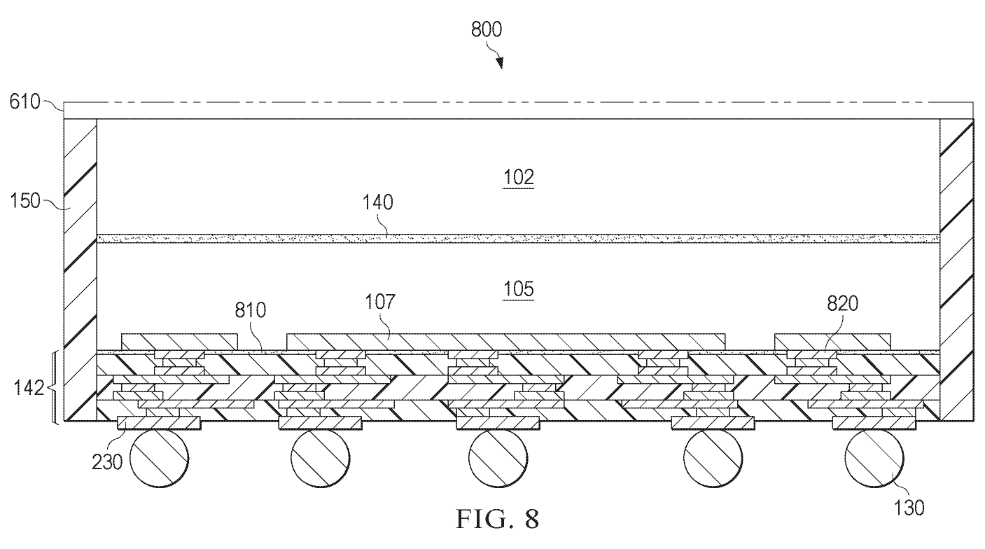

FIG. 8 is a side cross-sectional view of an example MMIC 800 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, package material 150, LGA lands 230, and BGA solder balls 130. In the example shown in FIG. 8, the package material 150 has been ground off of, or otherwise removed from, the top of the heat spreader 102, but still covers the sides of the heat spreader 102, MMIC die 105, and RDL 142. Disposed upon the exposed surface of the heat spreader 102 may be an optional thermally conductive interfacial material (TIM) 610 that may for example interface with a heat sink (not shown). In the example shown in FIG. 8, the MMIC die 105 and active circuit plane 107 are coated with an optional MMIC coat 810. The MMIC coat 810 may include a dielectric material layer configured to affect (e.g., increase) the quality factor (Q) on inductive elements, such as an air bridge on the MMIC. The MMIC coat may for example comprise a low dielectric constant (k) material such as nano-porous SiOxCy, UV-curable epoxy, or other suitable material, penetrated by conductive vias or posts 820 that connect the active circuit plane 107 to the RDL 142.

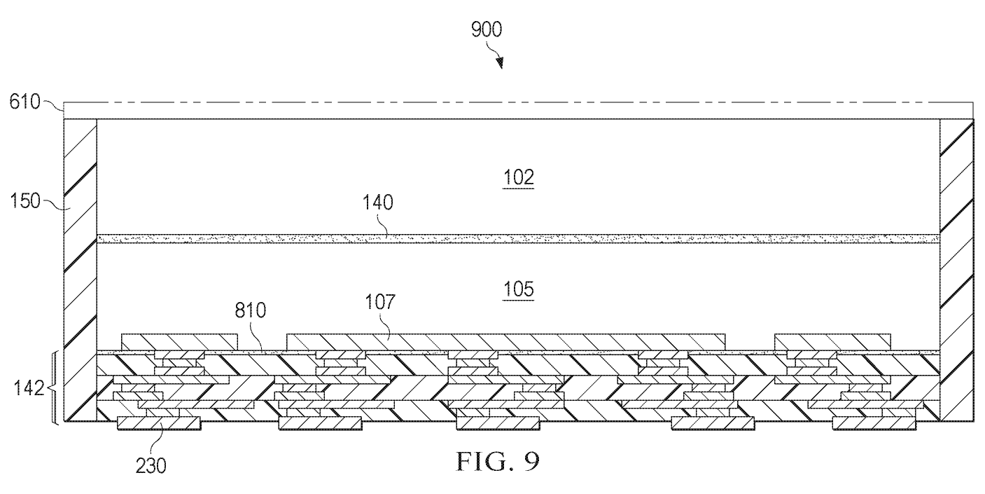

FIG. 9 is a side cross-sectional view of an example MMIC 900 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, package material 150, LGA lands 230, and BGA solder balls 130. In the example shown in FIG. 9, the package material 150 has been ground off of, or otherwise removed from, the top of the heat spreader 102, but still covers the sides of the heat spreader 102, MMIC die 105, and RDL 142. Disposed upon the exposed surface of the heat spreader 102 is the optional thermally conductive interfacial material (TIM) 610, and disposed on the bottom or front of the the MMIC die 105 and active circuit plane 107 is the optional MMIC coat 810, penetrated by conductive vias or posts 820 that connect the active circuit plane 107 to the RDL 142.

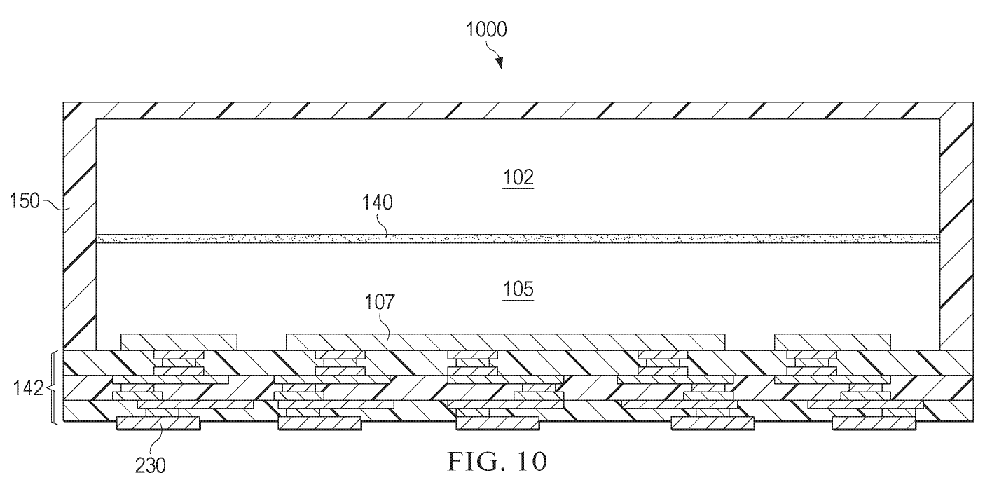

FIG. 10 is a side cross-sectional view of an example MMIC 1000 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, package material 150, and LGA lands 230. In the example shown in FIG. 10, the package material 150 covers the top of the heat spreader 102, as well as the sides of the heat spreader 102, and MMIC die 105. However, the package material 150 does not cover the sides of the RDL 142, which has been built up all the way to the edge of the package material 150.

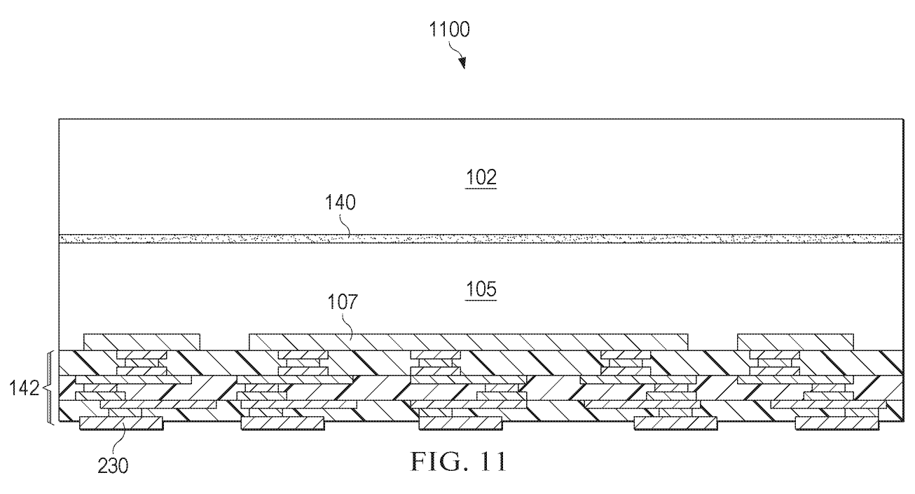

FIG. 11 is a side cross-sectional view of an example MMIC 1100 with non-metallic heat spreader 102 and RDL 142, in accordance with at least one embodiment of the present disclosure. Visible are the heat spreader 102, MMIC die 105, micro bond line attachment (MBLA 140), active circuit layer 107, RDL 142, and LGA lands 230. In the example shown in FIG. 11, the package material 150 is entirely absent, creating an uncovered MMIC configuration that provides thermal advantages as well as mechanical space advantages for a given application.

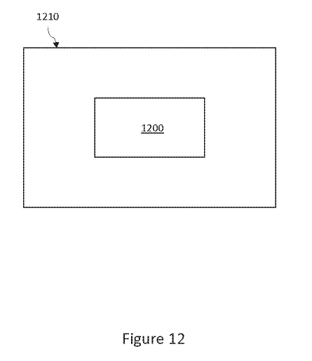

FIG. 12 is a schematic, diagrammatic view of an electronic device or a wireless device 1210 comprising a MMIC 1200, in accordance with at least one embodiment of the present disclosure. In some implementations, the electronic device or wireless device 1210 may include, for example, but not limited to, a computer, a cellular device, a satellite communication device, a wi-fi device, a radar, a global position system device, or any wireless device. In one or more embodiments, the MMIC 1200 may include a MMIC die mounted to a non-metallic heat spreader and redistribution layer, such as MMIC 100 of FIG. 1, MMIC 200 of FIG. 2, MMIC 400 of FIG. 4, MMIC 800 of FIG. 8, MMIC 500 of FIG. 5, MMIC 600 of FIG. 6, MMIC 700 of FIG. 7, MMIC 800 of FIG. 8, MMIC 900 of FIG. 9, MMIC 1000 of FIG. 10, MMIC 1100 of FIG. 11, or other MMIC comprising an MMIC die mounted to a non-metallic heat spreader and redistribution layer. The MMIC 1200 may implement any RF component used in wireless applications, as an example, such as one or more RF power amplifiers or in a radar or radar systems; and the MMIC 1200 may be coupled to other circuitry for implementing a wireless application.

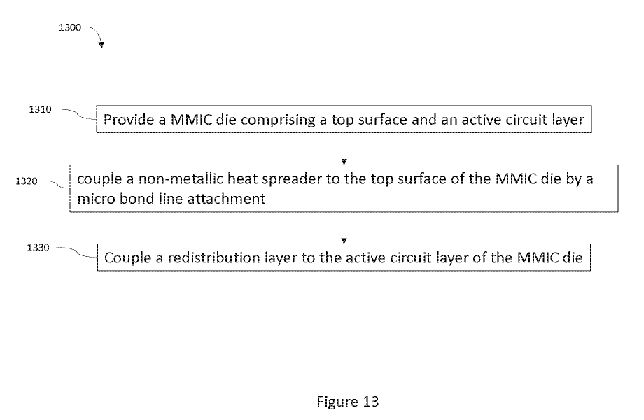

FIG. 13 is a schematic, diagrammatic representation, in flow diagram form, of an example MMIC fabrication method 1300, in accordance with at least one embodiment of the present disclosure. Flow diagrams are provided herein for exemplary purposes; a person of ordinary skill in the art will recognize myriad variations that nonetheless fall within the scope of the present disclosure. It is understood that the steps of method 1300 may be performed in a different order than shown in FIG. 13, additional steps can be provided before, during, and after the steps, and/or some of the steps described can be replaced or eliminated in other embodiments.

In step 1310, the method 1300 includes providing a MMIC die that includes a top surface and an active circuit layer. Execution then proceeds to step 1320.

In step 1320, the method 1300 includes coupling a non-metallic heat spreader to the top surface of the MMIC die by a micro bond line attachment. Execution then proceeds to step 1330.

In step 1330, the method 1330 includes coupling a redistribution layer to the active circuit layer of the MMIC die.

Novel elements of the present disclosure include:

Non-metallic (e.g., SiC) heat spreader bonded to the MMIC using the MBLA.

RDL deposed over the MMIC die active circuit plane.

All encapsulated with a package material into a MMIC scaled interconnect package.

Accordingly, it can be seen that the MMIC with non-metallic heat spreader and RDL advantageously provides heat dissipation, electrical insulation, and mechanical support that is superior to existing interposers, while providing an interconnectivity capability that does not exist in current heat spreaders.

A number of variations are possible on the examples and embodiments described above. For example, the package material, TIM layer, and MMIC coat may or may not be present, either singly or in combination. The number of metallic and dielectric layers in the redistribution layers (RDLs) can be 0, 1, 2, 3, 4, 5, or more. The MMIC die and/or heat spreader may be made from different materials than those described herein, while still performing the functions described above. Other devices or components may be attached or bonded to pads/vias of the RDL, including but not limited to wires, conductive traces, resistors, inductors, or capacitors. Multiple thermally dissipative interposers may be stacked, with or without other layers or components between them.

The logical units making up the embodiments of the technology described herein are referred to variously as objects, elements, components, modules, layers, etc. Furthermore, it should be understood that these may occur in any order, unless explicitly claimed otherwise or a specific order is inherently necessitated by the claim language.

All directional references e.g., upper, lower, inner, outer, upward, downward, left, right, lateral, front, back, top, bottom, above, below, vertical, horizontal, clockwise, counterclockwise, proximal, and distal are only used for identification purposes to aid the reader’s understanding of the claimed subject matter, and do not create limitations, particularly as to the position, orientation, or use of the MMIC with non-metallic heat spreader and RDL. Connection references, e.g., attached, coupled, connected, joined, or “in communication with” are to be construed broadly and may include intermediate members between a collection of elements and relative movement between elements unless otherwise indicated. As such, connection references do not necessarily imply that two elements are directly connected and in fixed relation to each other. The term “or” shall be interpreted to mean “and/or” rather than “exclusive or.” The word “comprising” does not exclude other elements or steps, and the indefinite article “a” or “an” does not exclude a plurality. Unless otherwise noted in the claims, stated values shall be interpreted as illustrative only and shall not be taken to be limiting.

The above specification, examples and data provide a complete description of the structure and use of exemplary embodiments of the MMIC with non-metallic heat spreader and RDL as defined in the claims. Although various embodiments of the claimed subject matter have been described above with a certain degree of particularity, or with reference to one or more individual embodiments, those skilled in the art could make numerous alterations to the disclosed embodiments without departing from the spirit or scope of the claimed subject matter.

Still other embodiments are contemplated. It is intended that all matter contained in the above description and shown in the accompanying drawings shall be interpreted as illustrative only of particular embodiments and not limiting. Changes in detail or structure may be made without departing from the basic elements of the subject matter as defined in the following claims.

What is claimed is:

1. A monolithic microwave integrated circuit (MMIC) device, comprising:
a MMIC die comprising a top surface and an active circuit layer;
a non-metallic heat spreader coupled to the top surface of the MMIC die by a micro bond line attachment; and
a redistribution layer coupled to the active circuit layer of the MMIC die.

2. The MMIC device of claim 1, wherein the MMIC die comprises silicon, gallium arsenide, or gallium nitride, or the non-metallic heat spreader comprises silicon carbide, aluminum nitride, or diamond, or the micro bond line attachment comprises a sintered metal.

3. The MMIC device of claim 1, wherein the non-metallic heat spreader has a thermal conductivity of at least 100 W/mK.

4. The MMIC device of claim 1, further comprising a package material at least partially covering the non-metallic heat spreader and MMIC die.

5. The MMIC device of claim 1, further comprising a thermally conductive interfacial material on a top surface of the non-metallic heat spreader.

6. The MMIC device of claim 1, further comprising a dielectric MMIC coat disposed between the active circuit layer and the redistribution layer.

7. The MMIC device of claim 1, further comprising a land grid array or ball grid array disposed on a bottom surface of the redistribution layer.

8. A method for packaging a monolithic microwave integrated circuit (MMIC), the method comprising:
providing a MMIC die comprising a top surface and an active circuit layer;
coupling a non-metallic heat spreader to the top surface of the MMIC die by a micro bond line attachment; and
coupling a redistribution layer to the active circuit layer of the MMIC die.

9. The method of claim 8, wherein the MMIC die comprises silicon, gallium arsenide, or gallium nitride, or the non-metallic heat spreader comprises silicon carbide, aluminum nitride, or diamond, or the micro bond line attachment comprises a sintered metal.

10. The method of claim 8, wherein the non-metallic heat spreader has a thermal conductivity of at least 100 W/mK.

11. The method of claim 8, further comprising covering at least a portion of the non-metallic heat spreader and MMIC die with a packaging material.

12. The method of claim 8, further comprising a coating a thermally conductive interfacial material on a top surface of the non-metallic heat spreader.

13. The method of claim 8, further comprising a coating a dielectric MMIC material between the active circuit layer and the redistribution layer.

14. The method of claim 8, further comprising coupling a land grid array or ball grid array to a bottom surface of the redistribution layer.

15. A wireless device comprising:
a monolithic microwave integrated circuit (MMIC) device, comprising:
a MMIC die comprising a top surface and an active circuit layer;
a non-metallic heat spreader coupled to the top surface of the MMIC die by a micro bond line attachment;
a redistribution layer coupled to the active circuit layer of the MMIC die; and
a land grid array or ball grid array disposed on a bottom surface of the redistribution layer.

16. The wireless device of claim 15, wherein the MMIC die comprises silicon, gallium arsenide, or gallium nitride, or the non-metallic heat spreader comprises silicon carbide, aluminum nitride, or diamond, or the micro bond line attachment comprises a sintered metal.

17. The wireless device of claim 15, wherein the non-metallic heat spreader has a thermal conductivity of at least 100 W/mK.

18. The wireless device of claim 15, further comprising a package material at least partially covering the non-metallic heat spreader and MMIC die.

19. The wireless device of claim 15, further comprising a thermally conductive interfacial material on a top surface of the non-metallic heat spreader.

20. The wireless device of claim 15, further comprising a dielectric MMIC coat disposed between the active circuit layer and the redistribution layer.
